(19) United States
(12) Patent Application Publication
(10) Pub. No.: US 2025/0379121 A1
(43) Pub. Date: Dec. 11, 2025

(54) MEMORY WITH COOLING SYSTEMS USING THROUGH-SILICON TRENCHES, AND ASSOCIATED SYSTEMS, DEVICES, AND METHODS

(71) Applicant: Micron Technology, Inc., Boise, ID (US)

(72) Inventors: Raghukiran Sreeramaneni, Frisco, TX (US); Nevil N. Gajera, Meridian, ID (US)

(21) Appl. No.: 19/221,257

(22) Filed: May 28, 2025

Related U.S. Application Data
(60) Provisional application No. 63/658,387, filed on Jun. 10, 2024.

(51) Int. Cl. H01L 23/46; H01L 23/31; H01L 25/18

(52) U.S. Cl. CPC H01L 23/46; H01L 23/3107; H01L 25/18

(57) ABSTRACT

Memory with cooling systems using through-silicon trenches (and associated devices and methods) are disclosed herein. In one embodiment, a high-bandwidth memory (HBM) device includes an interface die, a plurality of memory dies arranged in a stack and disposed over the interface die, and a cooling trench formed, at least in part, in two or more memory dies of the plurality. The cooling trench can extend from a top of the stack to a depth within the stack, and can be configured to receive a coolant for dissipating heat away from the two or more memory dies. In some embodiments, the cooling trench is a first cooling trench, and the HBM device can include a second cooling trench. The second cooling trench can be fluidly coupled to the first cooling trench, such as via a connector channel in a connector die that is positioned between the stack and the interface die.

### CROSS-REFERENCE TO RELATED APPLICATION(S)

The present application claims priority to U.S. Provisional Patent Application No. 63/658,387, filed Jun. 10, 2024, the disclosure of which is incorporated herein by reference in its entirety.

### TECHNICAL FIELD

The present disclosure generally relates to semiconductor devices. For example, several embodiments of the present disclosure are directed to memory devices (e.g., high-bandwidth memory (HBM) devices) with cooling systems using through-silicon trenches, and associated systems, devices, and methods.

### BACKGROUND

As semiconductor components become more compact and powerful, the risk of thermal-induced failures, degraded electrical performance, and reduced lifespan increases. This is particularly true as highly integrated system-in-package solutions become more widespread. For example, high-performance computation and memory devices are becoming integrated through increasingly tight heterogenous packaging solutions. Such devices can have large power consumption and associated thermal dissipation needs, which are increasing as packaging solutions continue to scale.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1 is a partially schematic cross-sectional side view of a system-in-package device configured in accordance with various embodiments of the present technology.

FIG. 2 is a partially schematic cross-sectional view of an HBM device configured in accordance with various embodiments of the present technology.

FIG. 3 is a partially schematic cross-sectional view of another HBM device configured in accordance with various embodiments of the present technology.

FIG. 4 is a flowchart illustrating a method for cooling a stacked semiconductor device in accordance with various embodiments of the present technology.

FIG. 5 is a flowchart illustrating another method for cooling a stacked semiconductor device in accordance with various embodiments of the present technology.

### DETAILED DESCRIPTION

The present disclosure is directed to memory with cooling systems using through-silicon trenches (TSTs), and associated systems, devices, and methods. For example, several embodiments described in detail below are directed to cooling stacked semiconductor devices, such as HBM devices (sometimes also referred to herein as “HBM cubes”) that can be coupled to a host device within a system-in-package (SiP) device. In one embodiment, an HBM device includes (a) a stack of memory dies and (b) an integrated cooling system having multiple cooling trenches that extend vertically through the stack of memory dies and that can be filled with a coolant. The coolant can remain generally stagnant within the cooling trenches such that heat dissipated to the coolant from memory dies in the stack is thermally conducted through and/or carried upward by the coolant. In other embodiments, the coolant can be pumped through the cooling trenches to increase a rate of heat dissipation from the memory dies.

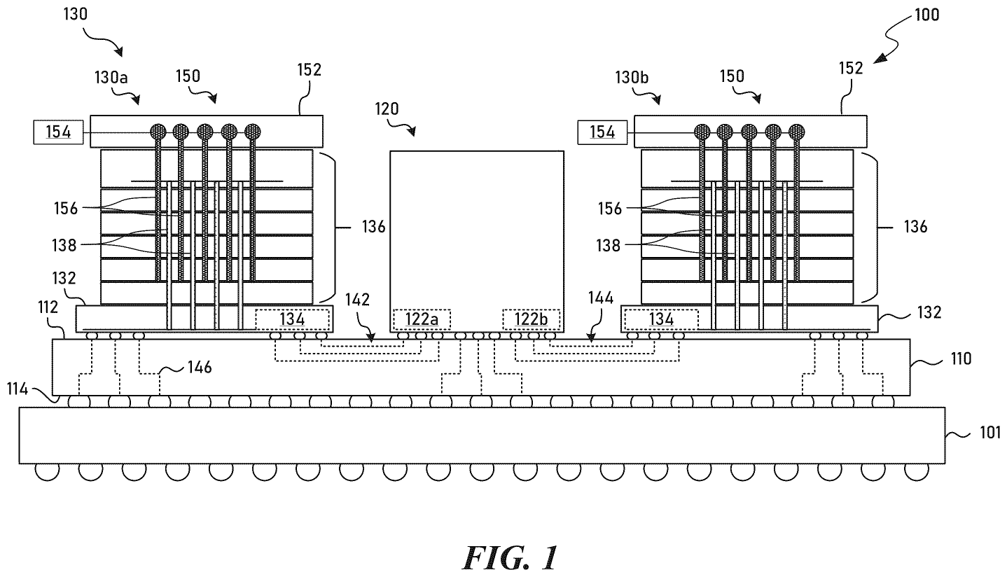

Specific details of several embodiments of the present technology are described herein with reference to FIGS. 1-5. For the sake of clarity and example, the present technology is primarily described below in the context of high-bandwidth memory devices, such as high-bandwidth memory cubes that each include a plurality of memory dies (e.g., arranged in one or more stacks and/or positioned laterally adjacent one another). The memory dies are primarily described below in the context of dies incorporating volatile storage elements, such as dynamic random-access memory (DRAM) storage elements. Memory dies configured in accordance with other embodiments of the present technology, however, can include other types of storage elements (e.g., in addition to or in lieu of DRAM storage elements), such as other types of volatile storage elements (e.g., static random-access memory (SRAM) storage elements) and/or non-volatile storage elements (e.g., NAND, NOR, phase change memory (PCM), ferroelectric random-access memory (FeRAM), resistive random-access memory (RRAM), and magnetic random-access memory (MRAM), among others). Additionally, or alternatively, the present technology can be applied in other types of memory devices (e.g., hybrid memory cubes) and/or in other semiconductor devices (e.g., other stacks of semiconductor dies or in non-stacked semiconductor devices). Moreover, a person of ordinary skill in the art will understand that embodiments of the present technology can have different configurations, components, and/or procedures than those shown or described herein, and/or that these and other embodiments can be without several of the configurations, components, and/or procedures shown or described herein without deviating from the present technology.

As used herein, the terms “vertical,” “lateral,” “upper,” “lower,” “top,” and “bottom” can refer to relative directions or positions of features in systems/devices in view of the orientation shown in the drawings. For example, “bottom” can refer to a feature of a system/device positioned closer to the bottom of a page than another feature. These terms, however, should be construed broadly to include systems/devices having other orientations, such as inverted or inclined orientations where top/bottom, over/under, above/below, up/down and left/right can be interchanged depending on the orientation.

High data reliability, high speed of memory access, lower power consumption, and reduced chip size are features that are demanded from semiconductor memory. In recent years, three-dimensional (3D) memory devices have been introduced. Some 3D memory devices are formed by stacking memory dies vertically, and interconnecting the dies using through-silicon (or through-substrate) vias (TSVs). Benefits of the 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 3D memory devices contribute to higher memory access speed, lower power consumption, and chip size reduction. Example 3D memory devices include hybrid memory cubes (HMC) and high-bandwidth memory (HBM) devices. For example, HBM is a type of memory that includes a vertical stack of memory dies (e.g., dynamic random-access memory (DRAM) dies) and an interface die (which, e.g., provides an interface between the memory dies of the HBM device and a host device).

In a typical SiP configuration, HBM devices may be integrated with a host device (e.g., a graphics processing unit (GPU), a computer processing unit (CPU), a tensor processing unit (TPU), and/or any other suitable processing unit) using a base substrate (e.g., a silicon interposer, a substrate of organic material, a substrate of inorganic material, and/or any other suitable material that provides interconnection between the host device and the HBM device and/or provides mechanical support for the components of a SiP device), through which the HBM devices and the host device communicate. Because traffic between the HBM devices and the host device resides within the SiP (e.g., using signals routed through the interposer), a higher bandwidth may be achieved between the HBM devices and the host device than in conventional systems. In other words, the TSVs interconnecting memory dies within an HBM device and route lines in the interposer (sometimes referred to collectively as part of a system bus) enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., GPU/CPU) and HBM devices during operation. For example, the high-bandwidth channels can be on the order of 1000 gigabytes per second (GB/s, sometimes also referred to as gigabits (Gb)). It will be appreciated that such high-bandwidth data transfer between a host device and memory dies of HBM devices can be advantageous in various high-performance computing applications, such as video rendering, high-resolution graphics applications, artificial intelligence and/or machine learning (AI/ML) computing systems and other complex computational systems, and/or various other computing applications.

Although incorporating a stacked arrangement of memory dies in an HBM or other semiconductor device offers several advantages, sufficient heat dissipation from the stacked arrangement remains a problem. For example, heat dissipated by memory dies of a stack can be at least partially trapped within the stack (e.g., between two or more of the memory dies). In fact, in some embodiments, a bottom-most memory dic (e.g., the memory die nearest an interface dic) in the stack can often dissipate more heat than memory dies positioned higher in the stack, resulting in a significant vertical temperature gradient across the stack. Moreover, as semiconductor components become more compact and powerful, and as packaging solutions continue to scale, the risks of thermal-induced failures, degraded electrical performances, and reduced lifespans grow. And conventional cooling systems that remove heat from only a top surface of a topmost memory die of a stack do not adequately address the issue because they leave heat dissipated deeper in the stack more or less trapped in the stack.

To address these concerns, several embodiments of the present technology are directed to semiconductor devices (e.g., HBM devices, SiP devices) that each include (i) a stack of dies (e.g., memory dies) and (ii) a corresponding cooling system having (a) a cooling body positioned over the stack of dies and (b) one or more cooling trenches that extend at least partially through the stack of dies. A coolant, such as a liquid (e.g., deionized water, a dielectric fluid), gas (e.g., air, helium, hydrogen), or another suitable type of coolant, can be introduced into the cooling trenches, and the coolant can carry away heat dissipated by the dies in the stack. In some embodiments, after being introduced into the cooling trenches, the coolant remains generally stagnant, and portions of the coolant that are heated by heat dissipated by the dies can rise toward the cooling body (e.g., by virtue of buoyancy). In these and other embodiments, the coolant can conduct heat upward toward the cooling body. In these and still other embodiments, the cooling system can further include a pump configured to pump or otherwise circulate the coolant through or along the cooling trenches in the stack, thereby increasing a rate of cooling provided by the cooling system.

The devices, systems, and methods of the present technology are therefore expected (a) to provide superior cooling to a stacked arrangement of dies in comparison to conventional cooling systems and (b) to significantly decrease a vertical temperature gradient (e.g., the difference in temperature between a top-most die and a bottom-most die of a stack) that is often observed in semiconductor devices, such as in HBM devices. In turn, the present technology is expected to reduce, mitigate, or eliminate the risks of thermal-induced failures, degraded electrical performances, and reduced lifespans due to insufficient heat dissipation from dies of a stack.

FIG. 1 is a partially schematic cross-sectional side view of a SiP device 100 configured in accordance with various embodiments of the present technology. As shown, the SiP device 100 includes an interposer 110 (or any other suitable base substrate) that is carried by a package substrate 101. The SiP device 100 also includes a host device 120 and a plurality of HBM devices 130 (two of which are identified individually in FIG. 1 as first HBM device 130a and second HBM device 130b). Each of the HBM devices 130 and the host device 120 are carried by and electrically coupled to (e.g., integrated with) an upper surface 112 of the interposer 110. Although shown as positioned at locations on the upper surface 112 of the interposer 110 that are laterally offset from the position of the host device 120, the HBM devices 130 can be stacked on top of the host device 120 in other embodiments of the present technology. The host device 120 (e.g., a GPU, CPU, TPU, and/or any other suitable processing unit) can include, among other features, a register and one or more levels of cache (e.g., an L1 cache, an L2 cache, and/or the like).

As further illustrated in FIG. 1, each of the HBM devices 130 (sometimes also referred to herein as “HBM cubes”) can include an interface die 132, one or more memory dies 136 (e.g., DRAM dies) carried by the interface die 132, and one or more through substrate vias 138 (“TSVs 138”) coupled to the interface die 132 and each of the memory dies 136. The TSVs 138 allow each of the dies in a corresponding HBM device 130 to communicate data (e.g., between the memory dies 136 and/or between one or more of the memory dies 136 and the interface die 132 (sometimes also referred to herein as a “base die,” a “logic die,” and/or the like).

The interface die 132 of an HBM device 130 can communicate with the host device 120. For example, a first host physical layer 122a (“first host PHY 122a”) in the host device 120 can be coupled to one or more first route lines 142 formed in the interposer 110. In turn, the first route lines 142 can be coupled to an HBM PHY 134 in the first HBM device 130a. As a result, the interface die 132 in the first HBM device 130a can be communicably coupled to the host device 120. Similarly, a second host PHY 122b in the host device 120 can be coupled to one or more second route lines 144 that are, in turn, coupled to an HBM PHY 134 in the second HBM device 130b. As a result, the interface die 132 in the second HBM device 130b can be communicably coupled to the host device 120. Similar to the TSVs 138, the first and second route lines 142, 144 can provide a high bandwidth (e.g., on the order of 1000 GB/s) channel through the interposer 110. As a result, each of the HBM devices 130 can expand an amount of memory that is accessible to the host device 120 via a high-bandwidth communication channel.

As illustrated in FIG. 1, the interposer 110 can further include one or more interconnects 146 extending between the upper surface 112 of the interposer 110 and a lower surface 114 of the interposer 110. The interconnects 146 can allow the host device 120 and/or the HBM devices 130 to send and/or receive signals (e.g., control signals, instructions, processing results, data, and/or the like) to and/or from, respectively, other devices coupled to the package substrate 101. In a specific, non-limiting example, the interconnects 146 can allow the HBM devices 130 to receive data from an external storage device (e.g., a NAND device) coupled to the package substrate 101.

As further illustrated in FIG. 1, each of the first and second HBM devices 130a, 130b include a cooling system 150 comprising (i) a cooling body 152 stacked with (e.g., on top of, over) the memory dies 136 and (ii) one or more cooling trenches 156 (also referred to herein as “through silicon trenches,” “TSTs,” or “trenches”) that extend at least partially through the corresponding stack of memory dies 136. A coolant, such as a liquid (e.g., deionized water, dielectric fluid), a gas, or another suitable type of coolant, can be disposed inside the cooling trenches 156, and the coolant can carry away heat dissipated by the memory dies 136 of the stack. In some embodiments, the coolant can remain generally stagnant in the cooling trenches 156 and portions of the coolant heated by the heat dissipated from the memory dies 136 can rise to the cooling body 152 (e.g., by virtue of buoyancy). In some embodiments, the coolant can conduct heat upward toward the cooling body 152. In these and other embodiments, the cooling system 150 can further include a pump 154 configured to pump or otherwise circulate the coolant through the trenches 156, thereby increasing the rate of cooling provided by the cooling system 150. The pump 154 can be included in or positioned external to the SiP device 100. Additionally, or alternatively, a flow rate of the coolant (e.g., controlled and/or achieved via operation of the pump 154) and/or a cooling rate of the stack of dies 136 can be predetermined or dynamically selected based on a current and/or desired vertical temperature gradient.

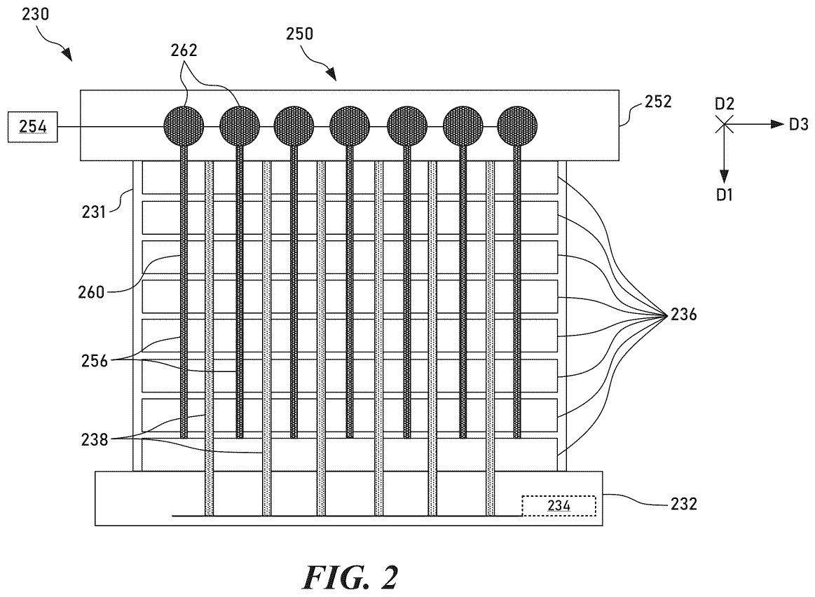

FIG. 2 is a partially schematic cross-sectional view of an HBM device 230 configured in accordance with various embodiments of the present technology. The HBM device 230 can identical or at least generally similar to one of the HBM devices 130 of FIG. 1. Therefore, similar references numbers are used across FIGS. 1 and 2 to denote identical or at least generally similar components.

As shown, the HBM device 230 includes an interface die 232, a stack of memory dies 236 disposed on the interface die 232, a plurality of TSVs 238 extending at least partway between the interface die 232 and a topmost memory die 236 of the stack, a cooling system 250, and an encapsulant 231 about at least part of the stack of memory dies 236. The interface die 232 can include an HBM PHY 234. In addition, the cooling system 250 includes a cooling body 252, an optional pump 254, and one or more cooling trenches 256 that extend at least partially through the stack of memory dies 236 of the HBM device 230. Although not shown in FIG. 2, the cooling system 250 can further include other components or assemblies, such as components or assemblies configured to lower a temperature of the cooling body 252.

The cooling body 252 can include or be made from metal (e.g., aluminum, steel) or another suitable material for removing heat (e.g., a material having a high thermal conductivity). As shown, the cooling body 252 includes one or more cooling cavities or channels 262 formed therein. In some embodiments, the cooling channels 262 extend through the cooling body 252 in a direction D2. While each of the cooling channels 262 has a circular cross-section in the illustrated embodiment, one or more of the cooling channels 262 can have triangular, rectangular, hexagonal, or other cross-sections in other embodiments. Additionally, or alternatively, the cooling channels 262 formed in the cooling body 252 can have the same or varying cross-sections and/or cross-sectional dimensions. In some embodiments, the pump 154 is in fluid communication with (or is otherwise operably coupled to) one or more of the cooling channels 262.

The cooling trenches 256 of the cooling system 250 can be in fluid communication with (or otherwise operably connected to) corresponding ones of the cooling channels 262, and can extend at least partway through the stack of memory dies 236 in a direction D1 (e.g., a same direction in which the memory dies 236 are stacked). In the illustrated embodiment, the cooling trenches 256 (also referred to herein as “through silicon trenches,” “TSTs,” or “trenches”) extend from the cooling channels 262 to a top surface of the bottom-most memory die 236 in the stack. In other embodiments, however, one or more of the cooling trenches 256 can extend to other depths in the stack of memory dies 236 (e.g., to the second-from-bottom-most memory die 236, to the third-from-bottom-most memory die 236, to a top surface of the interface die 232, to a location within or beneath the interface die 232). Moreover, different ones of the cooling trenches 256 can extend to different depths in the stack of memory dies 236 and/or in the interface die 232.

In the illustrated embodiment, the cooling trenches 256 and the TSVs 238 are shown interleaved with one another such that they are arranged in an alternating pattern and positioned generally along a same plane (e.g., such that they are simultaneously visible in the illustrated cross-section). In other embodiments, the cooling trenches 256 and the TSVs 238 can be arranged differently. For example, the cooling trenches 256 and the TSVs 238 can be arranged with one cooling trench 256 for every two TSVs 238 on the same plane (or vice versa), arranged such that the cooling trenches 156 and the TSVs 138 are positioned on or along different planes, arranged such that the cooling trenches 156 and the TSVs 138 are positioned on or along multiple planes, etc. In some embodiments, immediately adjacent ones of the cooling trenches 256 can be spaced apart from one another by a distance of about 10 μm, 15 μm, 20 μm, 25 μm, 30 μm, 10-30 μm, or another suitable distance. In some embodiments, each cooling trench 256 can have a cross-sectional dimension (e.g., diameter, width) of about 3 μm, 4 μm, 5 μm, 6 μm, 7 μm, 3-7 μm, or another suitable cross-sectional dimension. In these and other embodiments, cross-sectional dimensions of at least some of the trenches 256 can be the same as or vary from one another, and/or can be the same as or vary from cross-sectional dimensions of the TSVs 238. Other arrangements and dimensions of the cooling trenches 256 and the TSVs 238 are of course possible and within the scope of the present technology.

Various processes can be employed to form the cooling trenches 256. In some embodiments, the cooling trenches 256 can be formed in a manner generally similar to how the TSVs 238 are formed. For example, the cooling trenches 256 can be formed at desired locations using known TSV-manufacturing techniques, such as by using lasers, drilling holes, etching, or otherwise coring sections of desired lengths and widths. As a specific example, the cooling trenches 256 can be formed using a same or similar technique used to form apertures/holes corresponding to the TSVs 238. Such cooling trenches 256 can be formed at a same timing as, or at a different timing from, when the apertures/holes corresponding to the TSVs 238 are formed. In some embodiments, apertures/holes corresponding to the TSVs 238 can be filled with a first material, and the cooling trenches 256 can be filled with a second material having a lower melting point than the first material. At a later timing, such as after formation of the stack of memory dies 236 and/or after disposing or forming the stack on the interface die 232 of the HBM device 230, the HBM device 230 can be heated to a temperature between the melting points of the first material and the second material such that the second material in the cooling trenches 256 melts. The melted second material can then be removed (e.g., via suction or a blower), leaving the cooling trenches 256 free to receive a coolant 260. In another example, the cooling trenches 256 and the TSVs 238 can be filled with a same material or with different materials, and a reagent can be selectively introduced at locations corresponding to the cooling trenches 256 to decompose, etch, or otherwise remove the material filling the cooling trenches 256.

In some embodiments, the cooling trenches 256 are formed in individual memory dies 236, in smaller groupings/stacks of memory dies 236 than shown in FIG. 2, and/or before the memory dies 236 are stacked together to form the stack and/or the HBM device 230 shown in FIG. 2. For example, apertures or holes can be formed in each memory die 236, and the holes can then be aligned to form the cooling trenches 256 when stacking the memory dies 236. In other embodiments, the cooling trenches 256 are formed after the memory dies 236 are stacked together and/or disposed on the interface die 232. For example, as discussed above, apertures or holes can be formed through memory dies 236 of the stack in the direction D1. As a specific example, the encapsulant 231 can comprise a molding material that can be injected into a mold (not shown) surrounding the HBM device 230 at a packaging stage such that the encapsulant 231 at least partially surrounds the stack of memory dies 236 and/or is positioned between individual ones of the memory dies 236 of the stack. Once the molding material has hardened (e.g., cured), the cooling trenches 256 can be formed through the stack of memory dies 236 and the mold-based encapsulant 231.

As another specific example, the encapsulant 231 can comprise a stack of films (e.g., die attach films, non-conducting films) positioned around and/or in between the individual memory dies 236. In some embodiments, the films can be held together via adhesives. In some cases, the memory dies 236 can be stacked with the films to form the encapsulant 231, and the cooling trenches 256 can then be formed through the stack of memory dies 236 and the film-based encapsulant 231. In other cases, holes can be formed in the films and in the memory dies 236 before stacking, and the memory dies 236 and the films can thereafter be stacked such that the pre-formed holes in the memory dies 236 and the films are aligned to form the cooling trenches 256.

In some embodiments, inner walls of the cooling trenches 256 can include or be coated/otherwise covered with a liner material, such as with silicon oxide, silicon nitride, or another suitable material. In these and other embodiments, a liner material may also form at least part of the cooling trenches (e.g., by forming or defining sidewalls of the cooling trench, such as in areas between the memory dies 236 of the stack). A liner material can provide electrical, hermetic, and/or fluidic isolation between a coolant 260 within the cooling trenches 256 and other (e.g., electrical) components of the memory dies 236 and/or the HBM device 130. Additionally, or alternatively, the encapsulant 231 can provide and/or contribute to forming a hermetic and/or fluidic seal and thereby prevent leaking of coolant 260 from the trenches 256 and/or from between memory dies 236 of the stack (e.g., while also providing protection for the memory dies 236).

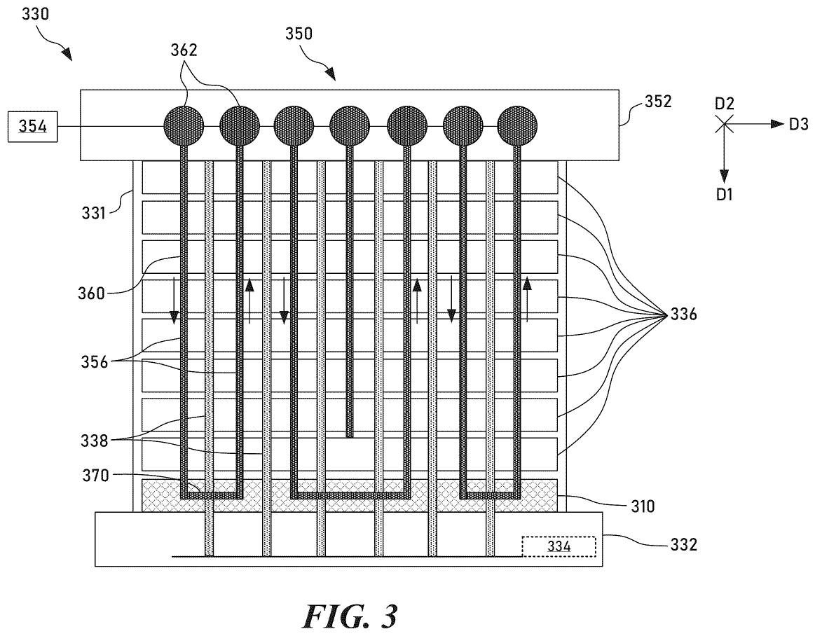

In some cases, it can be desirable to circulate a coolant throughout an HBM device, such as by fluidly or operably connecting two or more cooling trenches to form a pathway in the HBM device along which a coolant can be pumped into and out of a stack of memory dies. For example, FIG. 3 is a partially schematic cross-sectional view of another HBM device 330 configured in accordance with various embodiments of the present technology. The HBM device 330 can be identical or at least generally similar to one of the HBM devices 130 of FIG. 1. Therefore, similar references numbers are used across FIGS. 1 and 3 to denote identical or at least generally similar components.

As shown, the HBM device 330 is generally similar to the HBM device 230 of FIG. 2. For example, the HBM device 330 includes an interface die 332, a stack of memory dies 336 disposed on the interface die 332, a plurality of TSVs 338 extending at least partway between the interface die 332 and a topmost memory die 336 of the stack, a cooling system 350, and an encapsulant 331 about at least part of the stack of memory dies 336. The interface die 332 can include an HBM PHY 334. In addition, the cooling system 350 includes a cooling body 352, an optional pump 354, and one or more cooling trenches 356 that extend at least partially through the stack of memory dies 336 of the HBM device 330.

Unlike the HBM device 230 illustrated in FIG. 2, however, the HBM device 330 of FIG. 3 further includes a connector die 310 positioned between the bottom-most memory die 336 and the interface die 332. In some embodiments, the connector die 310 does not provide any electrical functionality and instead merely provides space within which connector channels 370 can be routed between two or more of the cooling trenches 356. More specifically, the connector die 310 can include one more connector channels 370 formed therein that facilitate laterally connecting (e.g., in a direction generally parallel to direction D3, in a direction generally parallel to a direction D2, and/or in a diagonal direction with respect to the directions D2 and D3) two or more of the cooling trenches 356. For example, the cooling trenches 356 can be arranged in pairs. Continuing with this example, a first cooling trench 356 of a pair can extend from a first cooling channel 362 in the cooling body 352 to a first location along a connector channel 370 formed in the connector die 310, and a second cooling trench 356 of the pair can extend from a second cooling channel 362 in the cooling body 352 to a second location along the connector channel 370. Coolant can be introduced from the first cooling channel 362 into the first cooling trench 356, transported downward along the first cooling trench 356 (as indicated by the downward pointing arrows) and into the connector channel 370 of the connector die 310, passed laterally along the connector channel 370 to the second cooling trench 356, and transported upward along the second cooling trench 356 (as indicated by the upward pointing arrows) to the second cooling channel 362. In some embodiments, the pump 354 can be used to circulate the coolant down the first cooling trench 356, along the connector channel 370, and up the second cool trenches 356.

In some embodiments, immediately adjacent ones of the cooling trenches 356 can be connected or paired, as shown by the left-most and right-most pairs of the cooling trenches 356 in FIG. 3. Additionally, or alternatively, non-adjacent ones of the cooling trenches 356 can be connected or paired, as shown by the cooling trenches 356 on either side of the center-most cooling trench 356 of the illustrated embodiment. In these and still other embodiments, cooling trenches 356 positioned on or along a same cross-sectional plane within the HBM device 330 can be connected or paired, and/or cooling trenches 356 positioned on or along different cross-sectional planes within the HBM device 330 can be connected or paired.

As shown, the TSVs 338 extend through the connector die 310. Although the connector channels 370 and the TSVs 338 are shown intersecting one another in the illustrated embodiment, this is merely for illustrative purposes to show all components within FIG. 3. In practice, the connector channels 370 can be formed on a different cross-sectional plane from and/or be routed around at least some of the TSVs 338 such that the TSVs 338 do not intersect the connector channels 370.

As discussed above, the connector die 310 can be positioned between the stack of memory dies 336 and the interface die 332. As shown, this arrangement can facilitate extending the cooling trenches 356 fully through the bottom-most memory die 336 of the stack. In other embodiments, the connector die 310 can be positioned at another location within the HBM device 330, such as between any two of the memory dies 336 of the stack or beneath the interface die 332. In still other embodiments, the connector die 310 can be omitted, and connector channels similar to the connector channels 370 can be formed in the interface die 332 and/or in one or more of the memory dies 336.

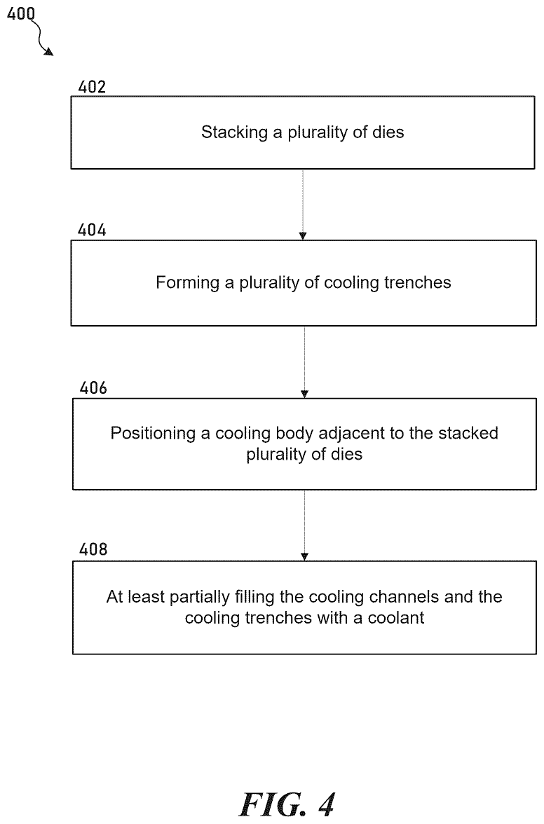

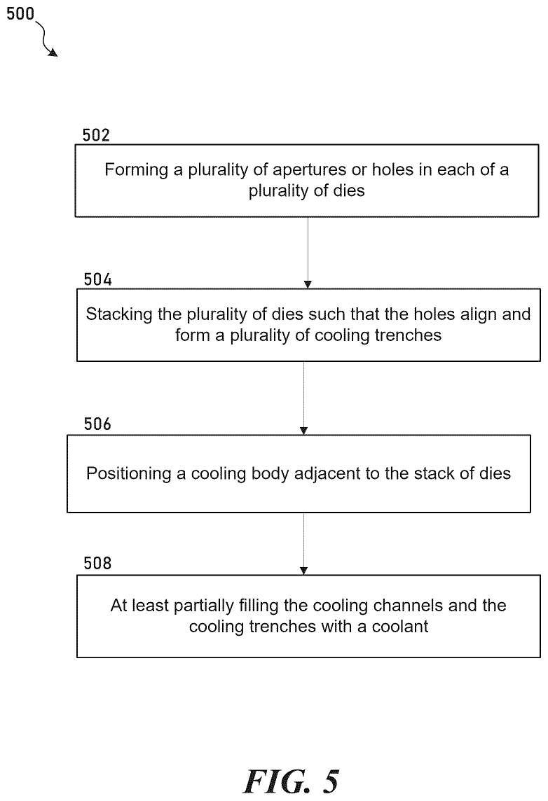

FIG. 4 is a flowchart illustrating a method 400 for cooling a stacked semiconductor device, such as an HBM device 130 of FIG. 1, the HBM device 230 of FIG. 2, and/or the HBM device 330 of FIG. 3. The method 400 is illustrated as a set of steps or blocks 402, 404, 406, and 408. All or a subset of one or more of the blocks 402, 404, 406, and/or 408 can be executed in accordance with the discussion above and/or with the discussion of FIG. 5 below.

The method 400 begins at block 402 by stacking a plurality of dies (e.g., memory dies). In some embodiments, stacking the plurality of dies can include stacking the plurality of dies on an interface die. In these and other embodiments, stacking the plurality of dies can include forming an encapsulant around and/or between one or more of the dies.

At block 404, the method 400 continues by forming a plurality of cooling trenches in the stack of dies. As discussed above with reference to FIG. 2, the cooling trenches can be formed with uniform or varying depths into the stack, uniform or varying spacing in between immediately adjacent cooling trenches and/or between a cooling trench and a TSV in the stack, uniform or varying cross-sections (e.g., diameters, widths), etc. As also discussed above with reference to FIG. 2, forming the plurality of cooling trenches can include lining the cooling trenches (e.g., with a liner material or layer), such as to fluidically or hermetically seal at least portions of the cooling trenches to prevent leakage of a coolant out from within those portions of the cooling trenches.

At block 406, the method 400 continues by positioning a cooling body adjacent to the stack of dies. In some embodiments, the cooling body includes a plurality of cooling channels. The cooling channels can be fluidly or operably connected to corresponding ones of the cooling trenches. Additionally, or alternatively, one or more of the cooling channels can be fluidly or operably connected to a pump.

At block 408, the method 400 continues by at least partially filling the cooling channels and the cooling trenches with a coolant. In some embodiments, after being introduced into the cooling channels and/or the cooling trenches, the coolant remains generally stagnant such that heat dissipated by the dies deeper in the stack (e.g., the bottom-most die 136) is carried by the coolant away from the dies and toward the cooling body for further dissipation. For example, the coolant can have a relatively high thermal conductivity such that the coolant conducts heat away from the dies. In another example, portions of the coolant that are heated by heat dissipated by the dies rise upward away from the dies and toward the cooling body by virtue of buoyancy.

In some embodiments, the coolant is transferred through or along the cooling channels and/or the cooling trenches. For example, a pump can be fluidly or operably coupled to one or more of the cooling channels such that the pump can actively transfer or circulate the coolant through the coolant channels and/or the cooling trenches. In another example, the coolant can be configured to be passively transferred through the cooling channels via, for example, capillary action.

Although the blocks 402, 404, 406, and 408 of the method 400 are discussed and illustrated in a particular order, the method 400 illustrated in FIG. 4 is not so limited. In other embodiments, the method 400 can be performed in a different order. In these and other embodiments, any of the blocks 402, 404, 406, and 408 of the method 400 can be performed before, during, and/or after any of the other blocks 402, 404, 406, and 408 of the method 400. For example, all or a subset of the block 404 can be executed at a same timing as and/or a timing that occurs before execution of all or a subset of block 402 (e.g., such that one or more of the cooling trenches are formed in the one or more of the dies before they are placed in the stack). Moreover, a person of ordinary skill in the relevant art will recognize that the illustrated method 400 can be altered and still remain within these and other embodiments of the present technology. For example, one or more of the blocks 402, 404, 406, and 408 of the method 400 illustrated in FIG. 4 can be omitted and/or repeated in some embodiments. As a specific example, the method 400 can include connecting two or more of the cooling trenches using one or more connector channels, such as connector channels formed in a connector die (e.g., positioned between the stack of dies and an interface die). As another specific example, cooling can be achieved without the cooling body. Thus, block 406 can be omitted in some embodiments while still introducing coolant into the cooling trenches.

FIG. 5 is a flowchart illustrating another method 500 for cooling a stacked semiconductor device, such as an HBM device 130 of FIG. 1, the HBM device 230 of FIG. 2, and/or the HBM device 330 of FIG. 3. The method 500 is illustrated as a set of steps or blocks 502, 504, 506, and 508. All or a subset of one or more of the blocks 502, 504, 506, and 508 can be executed in accordance with the discussion above.

The method 500 begins at block 502 by forming a plurality of apertures or holes in each of a plurality of dies. For example, the holes can be drilled, punched out, etched, or otherwise formed at a die manufacturing stage. As another example, the holes can be formed in individual dies or in a stackings of subsets representing less than all of the plurality of dies.

At block 504, the method 500 continues by stacking the plurality of dies such that the holes align and form a plurality of cooling trenches. In embodiments in which a film-based encapsulant is used, the holes can be formed in individual films (e.g., non-conducting films) and then aligned together with the holes in the dies (e.g., while stacking the plurality of dies). In some embodiments, once the cooling trenches are formed, but prior to filling the cooling channels and the cooling trenches with a coolant, the method 500 can include coating or otherwise lining portions of the inner walls of the cooling trenches with a liner material or layer, such as to fluidically or hermetically seal at least portions of the cooling trenches to prevent leakage of a coolant out from within those portions of the cooling trenches. In other words, coating or otherwise lining portions of the inner walls of the cooling trenches can provide electrical, hermetic, and/or fluidic isolation between coolant introduced into the cooling trenches and other (e.g., electrical) components of the dies (and/or the rest of a corresponding semiconductor device).

At block 506, the method 500 continues by positioning a cooling body adjacent to the stack of dies. In some embodiments, the cooling body includes a plurality of cooling channels. The cooling channels can be fluidly or operably connected to corresponding ones of the cooling trenches. Additionally, or alternatively, one or more of the cooling channels can be fluidly or operably connected to a pump.

At block 508, the method 500 continues by at least partially filling the cooling channels and the cooling trenches with a coolant. In some embodiments, after being introduced into the cooling channels and/or the cooling trenches, the coolant remains generally stagnant such that heat dissipated by the dies deeper in the stack is carried by the coolant away from the dies and toward the cooling body for further dissipation. For example, the coolant can have a relatively high thermal conductivity such that the coolant conducts the heat away from the dies. In another example, portions of the coolant that are heated by heat dissipated by the dies rise upward away from the dies and toward the cooling body by virtue of buoyancy.

In some embodiments, the coolant is transferred through or along the cooling channels and/or the cooling trenches. For example, a pump can be fluidly or operably coupled to one or more of the cooling channels such that the pump can actively transfer or circulate the coolant through the coolant channels and/or the cooling trenches. In another example, the coolant can be configured to be passively transferred through the cooling channels via, for example, capillary action.

Although the blocks 502, 504, 506, and 508 of the method 500 are discussed and illustrated in a particular order, the method 500 illustrated in FIG. 5 is not so limited. In other embodiments, the method 500 can be performed in a different order. In these and other embodiments, any of the blocks 502, 504, 506, and 508 of the method 500 can be performed before, during, and/or after any of the other blocks 502, 504, 506, and 508 of the method 500. For example, all or a subset of the block 504 can be executed at a same timing as and/or a timing that occurs before execution of all or a subset of block 502 (e.g., such that one or more of the cooling trenches are formed in the one or more of the dies after they are placed in the stack). Moreover, a person of ordinary skill in the relevant art will recognize that the illustrated method 500 can be altered and still remain within these and other embodiments of the present technology. For example, one or more of the blocks 502, 504, 506, and 508 of the method 500 illustrated in FIG. 5 can be omitted and/or repeated in some embodiments. As a specific example, cooling can be achieved without the cooling body. Thus, block 506 can be omitted in some embodiments while still introducing coolant into the cooling trenches. As another specific example, the method 500 can include connecting two or more of the cooling trenches using one or more connector channels, such as connector channels formed in a connector die (e.g., positioned between the stack of dies and an interface die).

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A high-bandwidth memory (HBM) device, comprising:
an interface die;
a plurality of memory dies arranged in a stack and disposed over the interface die; and
a cooling trench formed, at least in part, in two or more memory dies of the plurality, wherein the cooling trench extends from a top of the stack to a depth within the stack, and wherein the cooling trench is configured to receive a coolant for dissipating heat away from the two or more memory dies.

2. The HBM device of claim 1, wherein:
the cooling trench is a first cooling trench;
the depth is a first depth;
the two or more memory dies of the plurality are a first subset of memory dies of the plurality;
the HBM device further includes a second cooling trench formed, at least in part, in a second subset of the memory dies of the plurality; and
the second cooling trench (a) extends from the top of the stack to a second depth within the stack and (b) is configured to receive the coolant.

3. The HBM device of claim 2, wherein the second cooling trench is fluidly coupled to the first cooling trench within the HBM device.

4. The HBM device of claim 3, further comprising a connector die positioned between the stack and the interface die and including a connector channel extending between the first cooling trench and the second cooling trench, wherein the second cooling trench is fluidly coupled to the first cooling trench via the connector channel.

5. The HBM device of claim 3, wherein the HBM device is fluidly couplable to a pump such that the coolant is flown (i) from the top of the stack to within the stack along the first cooling trench and (ii) from within the stack to the top of the stack along the second cooling trench.

6. The HBM device of claim 2, wherein the second depth is different from the first depth.

7. The HBM device of claim 1, wherein the depth extends at least to a top surface of a bottommost memory die of the plurality of memory dies.

8. The HBM device of claim 1, further comprising a cooling body disposed over the stack and including a cooling channel fluidly coupled to the cooling trench.

9. The HBM device of claim 1, wherein the cooling trench includes a liner material configured, at least when the coolant is within the cooling trench, to electrically isolate the coolant from electrical components of the two or more memory dies.

10. The HBM device of claim 1, further comprising an encapsulant formed about at least part of the stack and configured, at least when the coolant is within the cooling trench, to hinder the coolant from exiting the stack between memory dies of the two or more memory dies.

11. A semiconductor device, comprising:
a plurality of dies arranged in a stack; and
a cooling trench extending at least partway through one or more dies of the plurality, wherein the cooling trench is configured to be at least partially filled with a coolant such that heat dissipated by the one or more dies is transferred away from the one or more dies.

12. The semiconductor device of claim 11, further comprising a cooling body coupled to the plurality of dies, wherein the cooling body includes a cooling channel that is fluidly connected to the cooling trench such that the coolant is transferrable between the cooling channel and the cooling trench.

13. The semiconductor device of claim 12, wherein:
the cooling trench is a first cooling trench;
the semiconductor device further comprises a second cooling trench extending at least partway through at least one die of the plurality;
the cooling channel is a first cooling channel; and
the cooling body includes a second cooling channel that is fluidly connected to the second cooling trench.

14. The semiconductor device of claim 13, where the second cooling trench is fluidly connected to the first cooling trench such that the coolant is transferrable from the first cooling trench to the second cooling trench without passing within the cooling body.

15. The semiconductor device of claim 14, further comprising a connector die coupled to the plurality of dies and including a connector channel extending between the first cooling trench and the second cooling trench, wherein the second cooling trench is fluidly connected to the first cooling trench via the connector channel.

16. The semiconductor device of claim 11, wherein:
the cooling trench is a first cooling trench;
the one or more dies are one or more first dies of the plurality; and
the semiconductor device further comprises—
a second cooling trench extending at least partway through one or more second dies of the plurality, wherein the second cooling trench is configured to be at least partially filled with the coolant such that heat dissipated by the one or more second dies is transferred away from the one or more second dies, and
a through-silicon via (TSV) extending at least partway through the one or more first dies and the one or more second dies, wherein the TSV is positioned between the first cooling trench and the second cooling trench.

17. The semiconductor device of claim 11, further comprising:
a liner material coating or defining at least part of sidewalls of the cooling trench, wherein the liner material is configured to provide a fluid-tight barrier that prevents the coolant, at least when the coolant is within the cooling trench, from exiting the cooling trench across at least the part of the sidewalls; or
an encapsulant surrounding at least part of the stack and configured, at least when the coolant is within the cooling trench, to prevent the coolant from exiting the stack.

18. A system-in-package (SiP) device, comprising:
an interposer;
a host device disposed over the interposer;
a plurality of high-bandwidth memory (HBM) devices disposed over the interposer, the plurality of HBM devices including a first HBM device and a second HBM device, wherein each of the first and second HBM devices includes (i) a stack of memory dies and (ii) a cooling trench extending at least partway through one or more memory dies of the stack; and
a cooling system configured to supply a coolant to the cooling trench of each of the first and second HBM devices.

19. The SiP device of claim 18, wherein the cooling system comprises:
a first cooling body (a) disposed over the stack of memory dies of the first HBM device and (b) including a first cooling channel fluidly coupled to the cooling trench of the first HBM device; and
a second cooling body (a) disposed over the stack of memory dies of the second HBM device and (b) including a second cooling channel fluidly coupled to the cooling trench of the second HBM device.

20. The SiP device of claim 18, wherein:
the cooling trench of the first HBM device is a first cooling trench;
the stack of memory dies of the first HBM device is a first stack of memory dies;
the first HBM device further includes (i) a connector die coupled to the first stack of memory dies and having a connector channel, and (ii) a second cooling trench extending at least partway through at least one memory die of the first stack, wherein the second cooling trench is fluidly coupled to the first cooling trench via the connector channel; and
the cooling system includes a pump configured to pump the cooling from the first cooling trench to the second cooling trench along the connector channel.
